(19) United States
(12) Patent Application Publication
(10) Pub. No.: US 2009/0039904 A1
(43) Pub. Date: Feb. 12, 2009

(54) Probe card, production method thereof and repairing method of probe card

(75) Inventors: Hidenori Kitazume, Tokyo (JP); Wataru Narazaki, Tokyo (JP); Koichi Wada, Tokyo (JP)

Correspondence Address: POSZ LAW GROUP, PLC, 12040 SOUTH LAKES DRIVE, SUITE 101, RESTON, VA, 20191, US

(73) Assignee: ADVANTEST CORPORATION, Tokyo (JP)

(21) Appl. No.: 11/660,525

(22) PCT Filed: Jan. 30, 2006
(86) PCT No.: PCT/JP2006/301465

§ 371 Date: Mar. 15, 2007

(51) Int. Cl. G01R 3/00; G01R 1/073

(52) U.S. Cl. 324/754; 29/874

(57) ABSTRACT

A probe card 6 is produced by forming probe pins 2, each having a thin film portion 21, three-dimensionally on a substrate 1 having a concave portion 11 formed thereon, forming bumps 3 at base end portions of the probe pins 2, moving the substrate 1 to the probe card substrate 4 side while supporting the same by a flip-chip bonder, bonding the probe pins 2 to pads 42 on said probe card substrate 4 via the bumps 3, then, moving the substrate 1 to the side separating from the probe card substrate 4 by the flip-chip bonder and rupturing the probe pins 2 at adjacent portions of the thin film portions 21 to mechanically remove the substrate 1 from the probe pins 2.

### TECHNICAL FIELD

The present invention relates to a probe card, a production method thereof and a repairing method of a probe card.

### BACKGROUND ART

When producing an IC device or other electronic device having a semiconductor integrated circuit, an operation test of the integrated circuit is normally conducted at a semiconductor wafer stage (front-end) to improve the production yield.

Normally, a prober is used for the test. The operation test of an integrated circuit is conducted by making a probe card provided with a large number of probe pins electrically connected to a test head close to a semiconductor wafer to be tested so as to bring the tip end portions of the probe pins electrically contact with external terminals of the semiconductor wafer and exchanging an electric signal.

As a method of producing the probe card, there is known a method of forming probe pins having a predetermined shape on a probe pin formation substrate made by silicon, etc., joining the probe pins with a probe substrate, and removing the probe pin formation substrate by etching so as to obtain a probe card configured that a plurality of probe pins are bonded on the probe substrate (the patent document 1).

[Patent Document 1] The Japanese Unexamined Patent Publication No. 2002-350465

### DISCLOSURE OF THE INVENTION

### Problem to be Solved by the Invention

In the above production method of a probe card, however, there has been a disadvantage that a step of removing the probe pin formation substrate by etching was cumbersome and time consuming.

Also, in recent years, probe pins have become minute as an integrated circuit becoming higher in density and pitches of external terminals of an electronic device becoming narrower thereby. In a probe card provided with such probe pins, when a part of the probe pins were deformed or damaged, etc., it was very difficult to repair only the defective probe pins manually because the probe pins were so minute.

The present invention was made in consideration of the above circumstances and has an object thereof to provide a probe card production method capable of producing a probe card easily, a probe card capable of having the probe pins repaired easily, and a method of repairing a probe card.

### Means for Solving the Problem

To attain the above object, firstly, the present invention provides a production method of a probe card, comprising the steps of forming probe pins on a substrate three-dimensionally, bonding pads on a probe card substrate to the probe pins on the substrate via bonding members, and mechanically removing the substrate from the probe pins (invention 1).

According to the invention (the invention 1), it is unnecessary to dissolve the entire substrate by etching and the substrate can be easily removed from the probe pins in a short time, accordingly, a probe card can be produced easily.

In the above invention (the invention 1), preferably, the substrate is removed from the probe pins by drawing the substrate apart from the probe pins (invention 2).

In the above invention (the invention 1), preferably, the probe pins on said substrate is bonded to the pads on said probe card substrate while supporting said substrate by a support device, then said substrate is removed from said probe pins by separating the substrate supported by said support device from said probe card substrate (invention 3).

In the above invention (the invention 1), it is preferable that a part with low mechanical strength is formed on each probe pin in advance (invention 4). According to the invention, the probe pins and the substrate can be separated at desired portions of the probe pins.

In the above invention (the invention 4), preferably, the part with low mechanical strength is formed as a thin film portion or an opening to the probe pin (invention 5).

In the above invention (the invention 5), preferably, a concave portion is formed on the substrate in advance, and a thin film portion or an opening on the probe pin is formed on the concave portion as a result that the probe pin is formed over the concave portion (invention 6). Normally, the probe pins can be formed by stacking and patterning metal films, however, when stacking metal films over the concave portion of the substrate, it is easy to form a thin film portion or opening on probe pins at the concave portion.

In the above invention (the invention 6), preferably, the concave portion is formed by etching (invention 7).

In the above invention (the invention 1), preferably, a plurality of probe pins are formed on the substrate in an arrangement corresponding to an arrangement of pads on the probe card substrate (invention 8). By using the probe pin formation substrate obtained by the invention, a plurality of probe pins can be bonded on the probe card substrate at a time, so that a production process of the probe card can be made short.

In the above invention (the invention 8), a plurality of probe pins obliquely extending from one direction are formed arranging in a line on a substrate, so that tip end portions thereof are arranged on a predetermined straight line; and a plurality of probe pins obliquely extending from another direction are formed arranging in a line on the substrate or on another substrate, so that tip end portions thereof are arranged on a predetermined straight line; and the former probe pin group and the latter probe pin group are bonded to pads on the probe card substrate, so that the tip end portions of the probe pins in the former probe pin group and the tip end portions of the probe pins in the latter probe pin group are alternately arranged (invention 9).

According to the above invention (the invention 9), tip end portions of the probe pins can be arranged at half the normal pitches, so that a probe card to be obtained can be applied to semiconductor wafers and electronic devices having external terminals at very narrow pitches.

In the above invention (the invention 1), preferably, bonding strength between the bonding members and the pads on the probe card substrate is smaller than bonding strength between a substrate body of the probe card substrate and the pads and than bonding strength between the probe pins and the bonding members (invention 10).

According to the above invention (the invention 10), even when a part of the probe pins are deformed or damaged, etc. and in need of repair, the probe pins together with the bonding members can be easily detached from pads of the probe card substrate by applying an external force to the probe pins to be repaired, so that the probe pins can be easily repaired.

Secondly, the present invention provides a probe card configured that probe pins are bonded to pads on a probe card substrate via bonding members, wherein bonding strength of the bonding members and the pads on the probe card substrate is smaller than bonding strength of the substrate body of the probe card substrate and the pads and than bonding strength between the probe pins and the bonding members (invention 11).

Thirdly, the present invention provides a probe card configured that probe pins are bonded to pads on a probe card substrate via bonding members, comprising a plurality of lining probe pins obliquely extending from one direction, wherein tip end portions thereof are arranged on a predetermined straight line; and a plurality of lining probe pins obliquely extending from another direction, wherein tip end portions thereof are arranged on the predetermined straight line; wherein the tip end portions of the probe pins in the former probe pin group and the tip end portions of the probe pins in the latter probe pin group are alternately arranged (invention 12).

Fourthly, the present invention provides a repairing method of a probe card for repairing probe pins on the probe card, wherein pads on a probe card substrate are bonded to probe pins via bonding members and bonding strength between the bonding members and the pads on the probe card substrate is smaller than bonding strength between a substrate body of the probe card substrate and the pads and than bonding strength between the probe pins and the bonding members; wherein an external force is applied to probe pins to be repaired so as to remove the probe pins together with the bonding members from pads on the probe card substrate and, then, substitute probe pins are bonded to the pads on the probe card substrate via bonding members (invention 13).

In the above invention (the invention 13), an external force may be applied to the probe pins by using a micro manipulator (invention 14), alternately, an external force may be applied to the probe pins by using a share tester (invention 15).

### ADVANTAGEOUS EFFECT OF THE INVENTION

According to the production method of a probe card of the present invention, a substrate can be easily removed from probe pins in a short time; accordingly, a probe card can be produced easily. Also, according to the probe card and the repair method of a probe card of the present invention, probe pins can be easily exchanged.

### BRIEF DESCRIPTION OF DRAWINGS

FIG. 1 is a partial sectional view from the side showing a step of a production method of a probe card according to an embodiment of the present invention.

FIG. 2 is a partial sectional view from the side showing a step of a production method of a probe card according to the same embodiment.

FIG. 3 is a partial sectional view from the side showing a step of a production method of a probe card according to the same embodiment.

FIG. 4 is a bottom plan view of a part of a substrate and a probe pin used in the production method of a probe card according to the same embodiment.

FIG. 5 is a perspective view showing a part of a probe card according to an embodiment of the present invention.

FIG. 6 is a partial sectional view from the side showing a part of a probe card according to an embodiment of the present invention.

### EXPLANATION OF REFERENCES

1 . . . substrate
   11 . . . concave portion
2 . . . probe pin
   21 . . . thin film portion
3 . . . bump (bonding member)
4 . . . probe card substrate
   41 . . . substrate body
   42 . . . pad
5 . . . support device
6 . . . probe card

### BEST MODE FOR CARRYING OUT THE INVENTION

Below, an embodiment of the present invention will be explained based on the drawings.

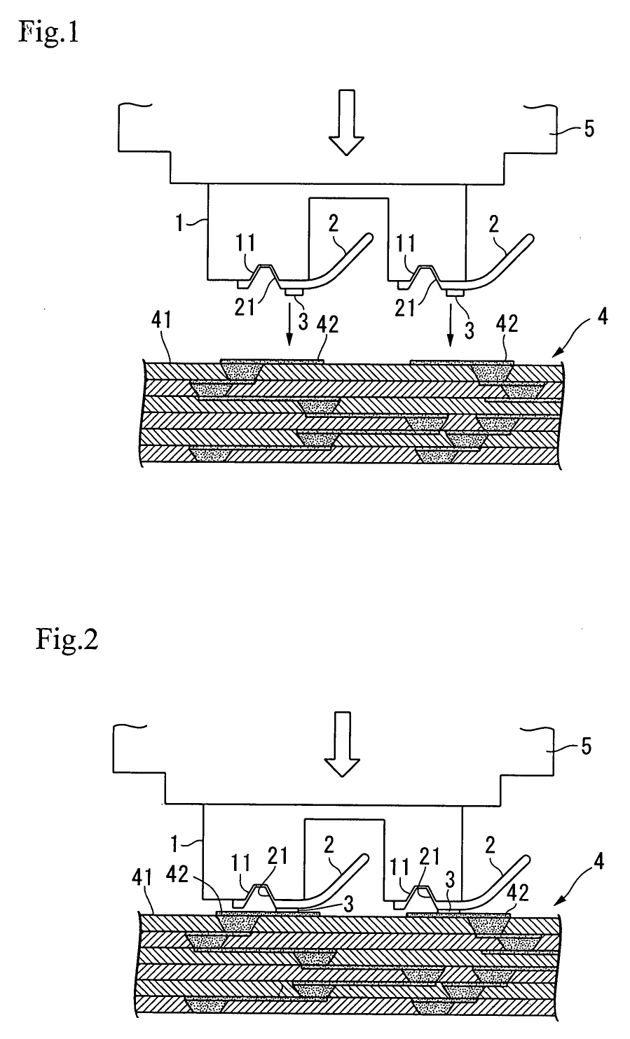

FIG. 1 to FIG. 3 are views showing a production method of a probe card according to an embodiment of the present invention.

First, as shown in FIG. 1, probe pins 2 three-dimensionally formed on a substrate 1 and a probe substrate 4 are produced, respectively. The probe substrate 4 can be produced by a normal method, and a surface of the substrate body 41 is provided with pads 42. As the probe substrate 4, for example, a build-up multilayer substrate subjected to impedance matching can be used.

The probe pins 2 can be formed on the substrate 1, for example, by using a MEMS technique. Specifically, by stacking and patterning metal films for composing the probe pins 2 on the substrate 1 made by silicon, the probe pins 2 can be formed three-dimensionally. According to the method, minute probe pins 2, for example, each having a length of several hundreds of μm, a width of 60 μm and a thickness of 20 μm or so can be formed.

In the present embodiment, after forming concave portions 11 on the substrate 1, probe pins 2 are formed to be a film over the respective concave portions 11. As a result, each of the probe pins 2 has a thin film portion at the concave portion 11, alternately, has an opening depending on a depth of the concave portion 11. Parts adjacent to the thin film portion or opening become parts with low mechanical strength on the probe pin 2. In the present embodiment, as an example, a thin film portion 21 of the probe pin 2 is shown in FIG. 1 to FIG. 4.

The concave portions 11 on the substrate 1 are preferably formed by etching. A shape of the concave portion 11 may be continuously arranged rectangular shapes as shown in FIG. 4(a) or a straight line shape as shown in FIG. 4(b). In either case, a position of the concave portion 11 is adjacent to a base end portion (opposite end portions of the tip end portions of the probe pins 2) where the probe pins 2 contact with the probe card substrate 4.

To form an effective thin film portion or opening on the probe pin 2, a depth of the concave portion 11 on the substrate 1 is preferably 10 to 15 μm.

On the substrate 1, it is preferable that a plurality of probe pins 2 are formed in an arrangement corresponding to an arrangement of pads 42 on the probe card substrate 3. As a result, a plurality of probe pins 2 can be brought to contact with the probe card substrate 4 at a time, and a process of producing the probe card can be made short.

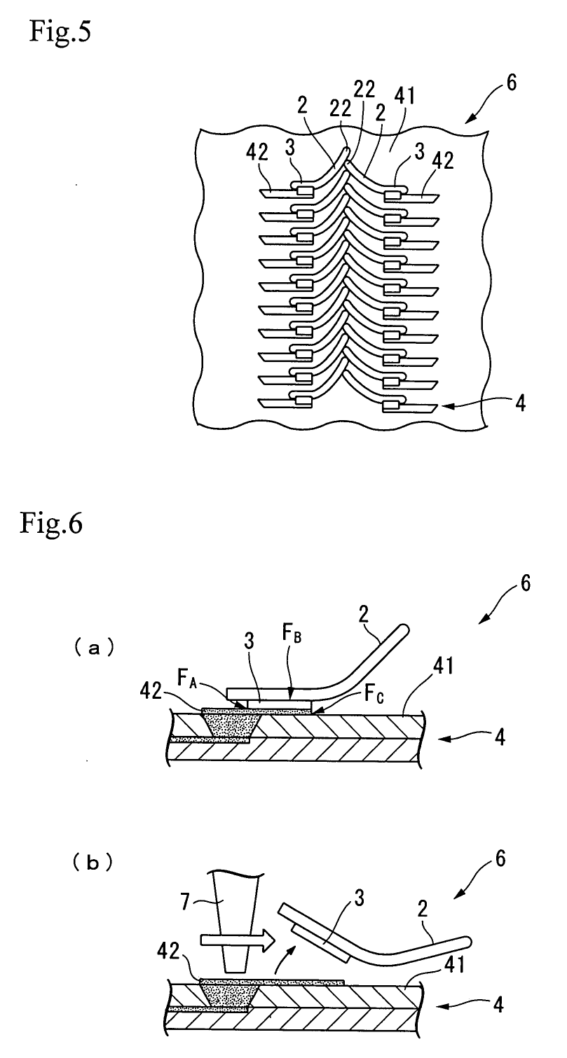

Here, when producing a probe card 6 as shown in FIG. 5, it is preferable that a plurality of probe pins 2 obliquely extending from one direction are formed arranging in a line (the plurality of probe pins 2 are referred to as a first probe pin group) on the substrate 1, so that the tip portions (portions to contact with external terminals of a semiconductor wafer or electronic device) are arranged on a predetermined straight line; and, at the same time, a plurality of probe pins 2 obliquely extending from another direction are formed arranging in a line (the plurality of probe pins 2 are referred to as a second probe pin group) on the same or another substrate 1, so that the tip portions are arranged on a predetermined straight line.

As shown in FIG. 1, at the base end portions of the probe pins 2, bumps 3 are formed as bonding members. As a material of the bumps 3, for example, gold, an alloy of gold and tin, an alloy of silver and tin and solder, etc. may be used. Note that the bumps 3 may be formed on the pads 42 side of the probe card substrate 4 or on both of the probe pins 2 side and pads 42 side.

Note that a protruding portion for contacting with an external terminal of a semiconductor wafer or electronic device is preferably formed at a tip end portion of each probe pin 2. Due to the provision of the protruding portion, the probe pin 2 becomes capable of being electrically connected to an external terminal of a semiconductor wafer or electronic device surely. The protruding portion may be formed by plating and jet printing.

In the present embodiment, as shown in FIG. 1, the substrate 1 is supported by a support device, such as a flip-chip bonder. By using a flip-chip bonder, a position of the supported substrate 1 can be controlled with high accuracy.

Next, as shown in FIG. 2, the support device is driven to move the substrate 1 to the probe card substrate 4 side to bring the bumps 3 on the probe pins 2 contact with the pads 42 on the probe card substrate 4. Then, under a condition where an adhesive force of the bumps 3 is brought out, the probe pins 2 and the pads 42 on the probe card substrate 4 are bonded via the bumps 3.

At this time, it is preferable that bonding strength F_{A} between the bumps 3 and the pads 42 is smaller than bonding strength F_{B} between the probe pins 2 and the bumps 3 and than bonding strength F_{C} between the substrate body 41 of the probe card substrate 4 and the pads 42 (refer to FIG. 6(a)). As a result, repairing of the probe pins 2 becomes easier as will be explained later on.

The bonding strength F_{A} between the bumps 3 and the pads 42 can be controlled by a size (surface area) of the bumps 3 formed at the base end portions of the probe pins 2 or by adjusting a condition at the time of bonding the bumps 3 to the pads 42 on the probe card substrate 4, for example, a temperature, pressure, power of ultrasonic wave and time thereof, etc.

Note that, when producing a probe card 6 as shown in FIG. 5, tip end portions of probe pins 2 in the first probe pin group and tip end portions of probe pins 2 in the second probe pin group are alternately arranged, and the probe pins in the first probe pin group and the probe pins 2 in the second probe pin group are respectively bonded to pads 42 of the probe card substrate 4.

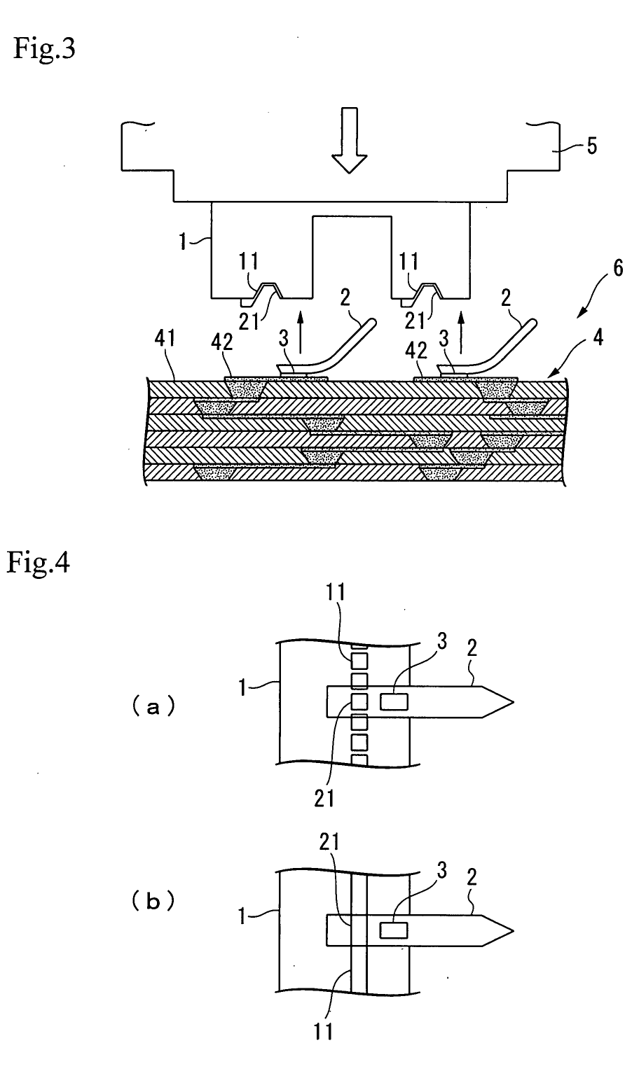

Next, as shown in FIG. 3, the support device is driven to bring the substrate 1 away from the probe card substrate 4. At this time, each probe pin 2 has a thin film portion 21 formed thereon in the present embodiment and a portion adjacent to the thin film portion 21 has low mechanical strength, so that the probe pin 2 is ruptured at the portion adjacent to the thin film portion 21, that is, at the end of the base end portion of the probe pin 2 bonded to a pad 42 on the probe card substrate 4. According to the present embodiment, as explained above, the substrate 1 can be mechanically removed from the probe pin 2 easily in a short time.

Note that, when using the first probe pin group and second probe pin group, a probe card 6 as shown in FIG. 5 is obtained. In this probe card 6, a plurality of lining probe pins 2 obliquely extending from one direction arranged so that the tip end portions are on a predetermined straight line (the first probe pins group) and a plurality of lining probe pins 2 obliquely extending from another direction arranged so that the tip end portions are on a predetermined straight line (the second probe pin group) are provided, and the tip end portions of the probe pins 2 in the first probe pin group and the tip end portions of the probe pins 2 in the second probe pin group are alternately arranged.

In such a probe card 6, the tip end portions of the probe pins 2 can be arranged at half the normal pitches, so that the probe card 6 can be used for a semiconductor wafer or electronic device having external terminals at very narrow pitches.

Here, at the time of bonding the probe pins 2 to the pads 42 on the probe card substrate 4, when bonding strength F_{A} between the bumps 3 and pads 42 is smaller than bonding strength F_{B} between the probe pins 2 and the bumps 3 and than bonding strength F_{C} between the substrate body 41 of the probe card substrate 4 and the pads 42, even if a part of the probe pins is deformed or damaged, etc. to be in need of repair, as shown in FIG. 6(b), the probe pins 2 to be repaired together with the bumps 3 can be easily removed from the pads 42 on the probe card substrate 4 by applying an external force to the probe pins 2 to be repaired by a moving member 7.

As the moving member 7, for example, those provided with a micro manipulator or a share tester capable of attaining highly accurate position control are preferably used. By using such a device, it is possible to target and remove only probe pins 2 to be repaired even when the probe pins 2 are minute.

After that, it is sufficient if substitute probe pins 2 are bonded to the pads 42 via bumps 3. At this time, the probe pins 2 can be bonded in the same method as in the production method of a probe card explained above.

By using the repairing method explained above, probe pins 2 can be easily repaired without any manual operation.

The embodiments explained above are described to facilitate understanding of the present invention and is not to limit the present invention. Accordingly, respective elements disclosed in the above embodiments include all design modifications and equivalents belonging to the technical scope of the present invention.

For example, instead of forming a thin film portion or an opening on the probe pin 2 on the substrate 1, an easily drawn-apart material may be formed between the substrate 1 and the probe pin 2.

### INDUSTRIAL APPLICABILITY

The present invention is useful for producing and repairing a probe card having minute probe pins.

1. A production method of a probe card, comprising the steps of:
forming probe pins on a substrate three-dimensionally;
bonding pads on a probe card substrate to the probe pins on said substrate via bonding members; and
mechanically removing said substrate from said probe pins.

2. The production method of a probe card as set forth in claim 1, wherein said substrate is removed from said probe pins by drawing said substrate apart from said probe pins.

3. The production method of a probe card as set forth in claim 1, wherein the probe pins on said substrate is bonded to the pads on said probe card substrate while supporting said substrate by a support device, then said substrate is removed from said probe pins by separating the substrate supported by said support device from said probe card substrate.

4. The production method of a probe card as set forth in claim 1, wherein a part with low mechanical strength is formed on each probe pin in advance.

5. The production method of a probe card as set forth in claim 4, wherein the part with low mechanical strength is formed as a thin film portion or an opening to said probe pin.

6. The production method of a probe card as set forth in claim 5, wherein a concave portion is formed on said substrate in advance, and a thin film portion or an opening on the probe pin is formed on said concave portion as a result that the probe pin is formed over said concave portion.

7. The production method of a probe card as set forth in claim 6, wherein said concave portion is formed by etching.

8. The production method of a probe card as set forth in claim 1, wherein a plurality of probe pins are formed on said substrate in an arrangement corresponding to an arrangement of pads on said probe card substrate.

9. The production method of a probe card as set forth in claim 8, a plurality of probe pins obliquely extending from one direction are formed arranging in a line on a substrate, so that tip end portions thereof are arranged on a predetermined straight line; and a plurality of probe pins obliquely extending from another direction are formed arranging in a line on said substrate or on another substrate, so that tip end portions thereof are arranged on a predetermined straight line; and the former probe pin group and the latter probe pin group are bonded to pads on the probe card substrate, so that the tip end portions of the probe pins in the former probe pin group and the tip end portions of the probe pins in the latter probe pin group are alternately arranged.

10. The production method of a probe card as set forth in claim 1, wherein bonding strength between said bonding members and the pads on said probe card substrate is smaller than bonding strength between a substrate body of said probe card substrate and the pads and than bonding strength between said probe pins and said bonding members.

11. A probe card, configured that probe pins are bonded to pads on a probe card substrate via bonding members, wherein
bonding strength of said bonding members and the pads on said probe card substrate is smaller than bonding strength of the substrate body of said probe card substrate and the pads and than bonding strength between said probe pins and said bonding members.

12. A probe card, configured that probe pins are bonded to pads on a probe card substrate via bonding members, comprising:
a plurality of lining probe pins obliquely extending from one direction, wherein tip end portions thereof are arranged on a predetermined straight line; and a plurality of lining probe pins obliquely extending from another direction, wherein tip end portions thereof are arranged on the predetermined straight line; wherein the tip end portions of the probe pins in the former probe pin group and the tip end portions of the probe pins in the latter probe pin group are alternately arranged.

13. A repairing method of a probe card for repairing probe pins on the probe card, wherein pads on a probe card substrate are bonded to probe pins via bonding members and bonding strength between said bonding members and the pads on said probe card substrate is smaller than bonding strength between a substrate body of said probe card substrate and the pads and than bonding strength between said probe pins and said bonding members; wherein
an external force is applied to probe pins to be repaired so as to remove said probe pins together with the bonding members from pads on said probe card substrate and, then, substitute probe pins are bonded to the pads on said probe card substrate via bonding members.

14. The repairing method of a probe card as set forth in claim 13, wherein an external force is applied to said probe pins by using a micro manipulator.

15. The repairing method of a probe card as set forth in claim 13, wherein an external force is applied to said probe pins by using a share tester.
